(19) United States
(12) Patent Application Publication
(10) Pub. No.: US 2023/0324132 A1
(43) Pub. Date: Oct. 12, 2023

(54) COOLING DEVICE

(71) Applicant: Nidec Corporation, Kyoto (JP)

(72) Inventors: Kengo INOUE, Kyoto (JP); Kazuhiro NISHIKAWA, Kyoto (JP); Yuta HORI, Kyoto (JP)

(21) Appl. No.: 18/129,952

(22) Filed: Apr. 3, 2023

(30) Foreign Application Priority Data
Apr. 8, 2022 (JP) 2022-064469

(51) Int. Cl. F28F 3/04; F28F 3/12

(52) U.S. Cl. CPC F28F 3/04; F28F 3/12

(57) ABSTRACT

A cooling device includes a liquid cooling jacket and a heat dissipator including a plate-shaped base portion extending in a first direction along a direction in which a refrigerant flows and in a second direction perpendicular or substantially perpendicular to the first direction and has a thickness in a third direction, a fin protruding from the base portion toward, a top plate portion provided at the fin, and a bent portion bent toward the one side in the third direction at an end on one side in the first direction of the top plate portion, with the one side in the first direction being a downstream side. Between the liquid cooling jacket and the top plate portion, a gap in the third direction is provided, and the bent portion opposes the liquid cooling jacket.

### CROSS-REFERENCE TO RELATED APPLICATIONS

The present application claims priority under 35 U.S.C. § 119 to Japanese Patent Application No. 2022-064469, filed on Apr. 8, 2022, the entire contents of which are hereby incorporated herein by reference.

### 1. FIELD OF THE INVENTION

The present disclosure relates to a cooling device.

### 2. BACKGROUND

Conventionally, a heat dissipator is used for cooling a heating element. The heat dissipator includes a base portion and a plurality of fins. The plurality of fins protrude from the base portion. The heat dissipator can be installed in a liquid cooling jacket. A flow path is formed by the base portion and the liquid cooling jacket. When a refrigerant flows through the flow path, the heat of the heating element moves to the refrigerant.

It is necessary to provide a certain gap (clearance) between the fin and the liquid cooling jacket. If there is no gap, the fin may be deformed when the base portion is attached to the liquid cooling jacket, and desired cooling performance may not be obtained. In addition, there is a possibility that the fin cannot be accommodated in the liquid cooling jacket due to positional variation when the fin is fixed to the base portion or assembly tolerance of the fin.

For this reason, a certain gap is provided in advance between the fin and the liquid cooling jacket. However, when a large amount of the refrigerant flows in this gap, an inflow amount of the refrigerant between the fins decreases, and there arises a problem that the ability to cool the fins decreases.

Therefore, it is known to suppress the refrigerant flowing in the gap by incorporating a flow path constituting member separate from the fin between the fin and the liquid cooling jacket. The flow path constituting member is, for example, a sheet-like rubber member. However, in such a configuration, there is a problem that mounting becomes complicated because the number of members constituting the flow path increases, or the flow path changes due to deformation of the flow path constituent member, which may affect cooling performance.

### SUMMARY

A cooling device according to an example embodiment of the present disclosure includes a liquid cooling jacket and a heat dissipator. The heat dissipator includes a plate-shaped base portion that extends in a first direction along a direction in which a refrigerant flows and in a second direction perpendicular or substantially perpendicular to the first direction, and has a thickness in a third direction perpendicular or substantially perpendicular to the first direction and the second direction, a fin protruding from the base portion toward one side in the third direction, a top plate portion provided at an end on the one side in the third direction, and a bent portion bent toward the one side in the third direction at at least one of an end on one side in the first direction or an end on other side in the first direction of the top plate portion, with the one side in the first direction being a downstream side. Between the liquid cooling jacket and the top plate portion, a gap in the third direction is provided, and the bent portion opposes the liquid cooling jacket.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a side sectional view of a cooling device according to a first example embodiment of the present disclosure.

FIG. 2 is a perspective view illustrating a partial configuration of a heat dissipation fin assembly.

FIG. 3 is a partially enlarged view of the upstream side of the configuration illustrated in FIG. 1.

FIG. 4 is a diagram illustrating a configuration of a bent portion according to a first modification of an example embodiment of the present disclosure.

FIG. 5 is a diagram illustrating a configuration of a bent portion according to a second modification of an example embodiment of the present disclosure.

FIG. 6 is a diagram illustrating a configuration of a bent portion according to a third modification of an example embodiment of the present disclosure.

FIG. 7 is a side cross-sectional view of a cooling device according to a second example embodiment of the present disclosure.

FIG. 8 is a diagram illustrating a configuration of a modification of the second example embodiment.

FIG. 9 is a side cross-sectional view of a cooling device according to a third example embodiment of the present disclosure.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is along a direction F in which a refrigerant W flows, and the downstream side is indicated by F1 and the upstream side is indicated by F2. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90 degrees. Each of the above-described directions does not limit a direction when a cooling device 5 is incorporated in various devices.

FIG. 1 is a side sectional view of a cooling device 5 according to a first example embodiment of the present disclosure. FIG. 1 is a diagram of a state in which the cooling device 5 is cut through a cross section perpendicular to the second direction at an intermediate position in the second direction, as viewed from one side in the second direction (front side on the sheet) to the other side in the second direction.

The cooling device 5 includes a liquid cooling jacket 4 and a heat dissipator 1. FIG. 1 illustrates the flow of a refrigerant W. One side in the first direction is a downstream side in a direction in which the refrigerant W flows, and the other side in the first direction is an upstream side in the direction in which the refrigerant W flows. The refrigerant W is liquid such as water.

The heat dissipator 1 includes a base portion 2 and a fin 3. The base portion 2 has a plate shape that extends in the first direction and the second direction and has a thickness in the third direction. The base portion 2 is made of a metal having high thermal conductivity such as a copper alloy, for example.

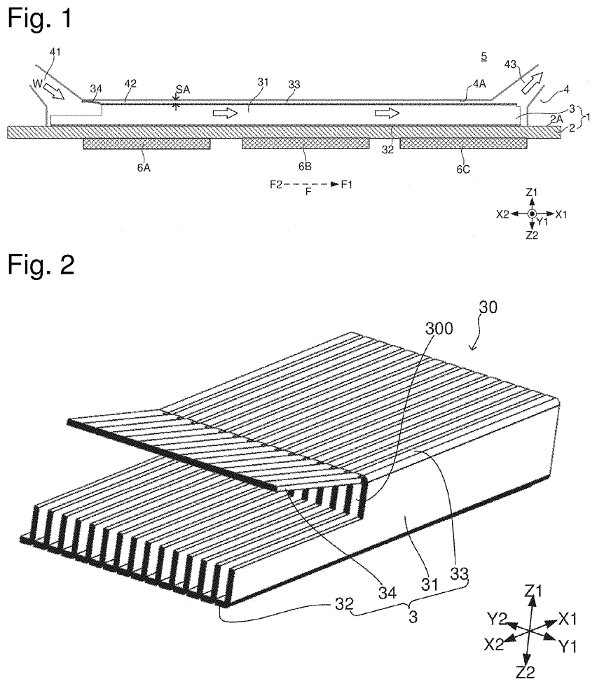

FIG. 2 is a perspective view illustrating a partial configuration of a heat dissipation fin assembly 30 configured of the fins 3. FIG. 2 illustrates a partial configuration of the fin 3 on the upstream side. The fin 3 is a metal plate extending in the first direction, and is formed of, for example, a copper plate. By stacking the plurality of fins 3 in the second direction, the heat dissipation fin assembly 30 is configured as a so-called stacked fin.

The fin 3 includes a side plate portion 31, a bottom plate portion 32, and a top plate portion 33. The side plate portion 31 has a flat plate shape extending in the first direction and the third direction with the second direction as the thickness direction. The bottom plate portion 32 is formed by being bent from an end on the other side in the third direction of the side plate portion 31 to the other side in the second direction. The top plate portion 33 is formed by being bent from an end on one side in the third direction of the side plate portion 31 to the other side in the second direction. The bottom plate portion 32 and the top plate portion 33 face each other in the third direction. Due to this, the fin 3 has a rectangular U-shaped cross section in a cross section orthogonal to the first direction. The fin 3 has a bent portion 34, which will be described later.

The heat dissipation fin assembly 30 formed of the fins 3 is attached to the base portion 2 by fixing the bottom plate portion 32 to a surface 2A (see FIG. 1) on one side in the third direction of the base portion 2 by, for example, brazing. Accordingly, the heat dissipator 1 has the fin 3 protruding from the base portion 2 toward one side in the third direction.

The heat dissipator 1 is attached to the liquid cooling jacket 4. The liquid cooling jacket 4 is, for example, a die-cast product made of a metal such as aluminum. The liquid cooling jacket 4 has a flow path therein for allowing the refrigerant W to flow.

Specifically, the liquid cooling jacket 4 includes an inlet flow path 41 disposed on the other side in the first direction, a refrigerant flow path 42, and an outlet flow path 43 disposed on one side in the first direction. The refrigerant flow path 42 is disposed between the inlet flow path 41 and the outlet flow path 43. The liquid cooling jacket 4 has a top surface 4A on one side in the third direction of the refrigerant flow path 42.

In a state where the heat dissipator 1 is not attached to the liquid cooling jacket 4, the top surface 4A is exposed to the other side in the third direction. The heat dissipator 1 is attached to the liquid cooling jacket 4 by fixing a side surface 2A on one side in the third direction of the base portion 2 in the heat dissipator 1 to a surface on the other side in the third direction of the liquid cooling jacket 4. In a state where the heat dissipator 1 is attached, the other side in the third direction of the top surface 4A is covered with the base portion 2, and the heat dissipation fin assembly 30 is accommodated in the refrigerant flow path 42.

The refrigerant W flowing from the outside of the liquid cooling jacket 4 into the inlet flow path 41 flows inside the inlet flow path 41 to one side in the first direction, and flows into the refrigerant flow path 42. The refrigerant W flowing through the refrigerant flow path 42 to one side in the first direction flows into the outlet flow path 43, and is discharged from the outlet flow path 43 to the outside of the liquid cooling jacket 4.

Heating elements 6A, 6B, and 6C (hereinafter, 6A and the like) are disposed on the other side in the third direction of the base portion 2. The number of heating elements may be a plural number other than three, or may be singular. The heat generated from the heating elements 6A and the like is transmitted from the base portion 2 and the heat dissipation fin assembly 30 to the refrigerant W flowing through the refrigerant flow path 42, whereby the heating elements 6A and the like are cooled.

As described above, the heat dissipator 1 includes the top plate portion 33 provided at one end in the third direction of the fin 3. As illustrated in FIG. 1, in the cooling device 5, a gap SA (clearance) in the third direction is formed between the top surface 4A and the top plate portion 33. That is, the gap SA in the third direction is provided between the liquid cooling jacket 4 and the top plate portion 33.

As illustrated in FIG. 2, a flow path 300 is formed between the fins 3 adjacent to each other in the second direction. When the amount of the refrigerant W flowing into the gap SA is large, the amount of the refrigerant W flowing into the flow path 300 is small, which is undesirable as cooling performance. Therefore, in the present example embodiment, the fin 3 is provided with the bent portion 34.

As illustrated in FIG. 2, the bent portion 34 is bent toward one side in the third direction at the end on the other side in the first direction of the top plate portion 33. That is, the heat dissipator 1 has the bent portion 34 that is bent toward one side in the third direction at the end on the other side in the first direction of the top plate portion 33. A plurality of the bent portions 34 are stacked in the second direction.

The bent portion 34 illustrated in FIG. 2 has a distal end facing the other side in the first direction. The bent portion 34 is configured as a leaf spring. As a result, when the heat dissipator 1 is attached to the liquid cooling jacket 4, the bent portion 34 comes into contact with the top surface 4A and is elastically deformed by a force applied to the other side in the third direction. In a state where the heat dissipator 1 is attached to the liquid cooling jacket 4 (state in FIG. 1), the bent portion 34 is in contact with the top surface 4A to continuously apply an elastic force to the top surface 4A. That is, the bent portion 34 faces the liquid cooling jacket 4. Here, they face each other in the third direction.

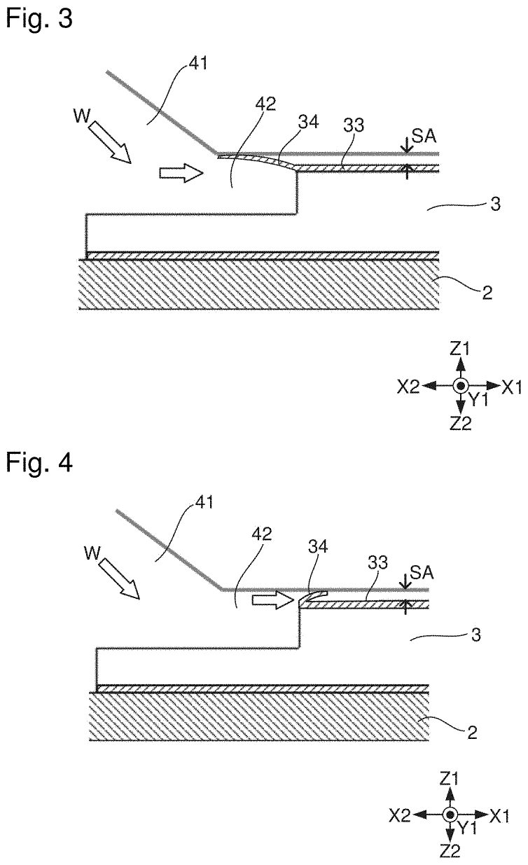

FIG. 3 is a partially enlarged view of the upstream side of the configuration illustrated in FIG. 1. As illustrated in FIG. 3, the bent portion 34 can seal the gap SA, and prevents the refrigerant W from flowing into the gap SA. Therefore, the refrigerant W can be guided to the flow paths 300 between the fins 3, and the cooling performance can be improved. In addition, since the bent portion 34 is integrated with the fin 3, a separate member for sealing the gap SA is unnecessary.

As illustrated in FIG. 3, the bent portion 34 faces the liquid cooling jacket 4 while being in contact with the liquid cooling jacket 4. Accordingly, the gap SA can be more reliably sealed.

The bent portion 34 is configured as a leaf spring. As a result, since the bent portion 34 comes into contact with the liquid cooling jacket 4 while applying elastic force to the liquid cooling jacket 4, the gap between the bent portion 34 and the liquid cooling jacket 4 is suppressed from widening.

As illustrated in FIG. 3, the distal end of the bent portion 34 bent from end on the other side in the first direction of the top plate portion 33 faces the other side in the first direction. As a result, when the refrigerant W collides with the bent portion 34 from the upstream side, the bent portion 34 is pushed toward the liquid cooling jacket 4 side, and the gap SA can be more reliably sealed.

When the heat dissipator 1 is attached to the liquid cooling jacket 4, the bent portion 34 may be plastically deformed to come into contact with the liquid cooling jacket 4.

In the configuration illustrated in FIG. 1, the bent portion 34 is provided on the upstream side, but the bent portion 34 may be provided at one end in the first direction of the top plate portion 33. That is, the heat dissipator 1 may include the bent portion 34 that is bent toward one side in the third direction at at least one of an end on one side in the first direction and an end on the other side in the first direction of the top plate portion 33.

FIG. 4 is a diagram illustrating a configuration of a bent portion 34 according to a first modification. In the configuration illustrated in FIG. 4, the bent portion 34 has a distal end facing one side in the first direction. Even with such a configuration, the gap SA can be sealed by the bent portion 34. However, in the configuration of FIG. 4, since there is a possibility that the bent portion 34 is deformed toward the other side in the third direction by the pressure of the refrigerant W and the gap between the bent portion 34 and the liquid cooling jacket 4 is widened, the above-described configuration of FIG. 3 can more reliably seal the gap SA.

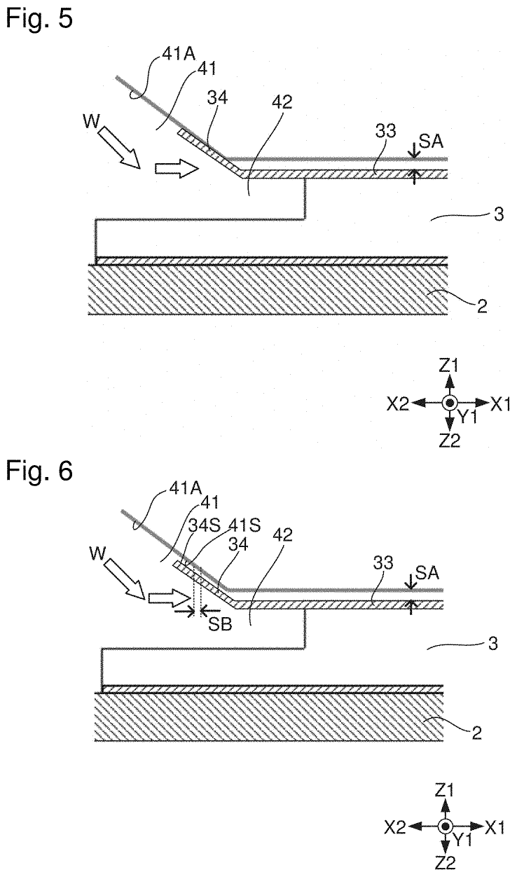

FIG. 5 is a diagram illustrating a configuration of a bent portion 34 according to a second modification. In the configuration shown in FIG. 5, the bent portion 34 is in surface contact with a wall portion 41A that is elastically deformed to form the inlet flow path 41. The wall portion 41A is connected to the other side in the third direction of the top surface 4A. That is, the bent portion 34 is in surface contact with the liquid cooling jacket 4 while facing the liquid cooling jacket 4 in the first direction. As a result, even when the refrigerant W collides with the bent portion 34, the bent portion 34 is pushed toward the wall portion 41A, so that the refrigerant W is further suppressed from flowing into the gap SA. The bent portion 34 may be brought into surface contact with the wall portion 41A in a plastically deformed state.

FIG. 6 is a diagram illustrating a configuration of a bent portion 34 according to a third modification. In the configuration illustrated in FIG. 6, unlike the second modification described above, the bent portion 34 is disposed with the gap SB in the first direction being interposed between it and the wall portion 41A. That is, the bent portion 34 has a second facing surface 34S facing a first facing surface 41S of the liquid cooling jacket 4 via the gap SB in the first direction. As a result, the refrigerant W collides with the bent portion 34 from the upstream side, whereby the bent portion 34 is deformed toward the liquid cooling jacket 4 side, and the second facing surface 34S of the bent portion 34 comes into contact with the first facing surface 41S of the liquid cooling jacket 4. Accordingly, the gap SA can be more reliably sealed.

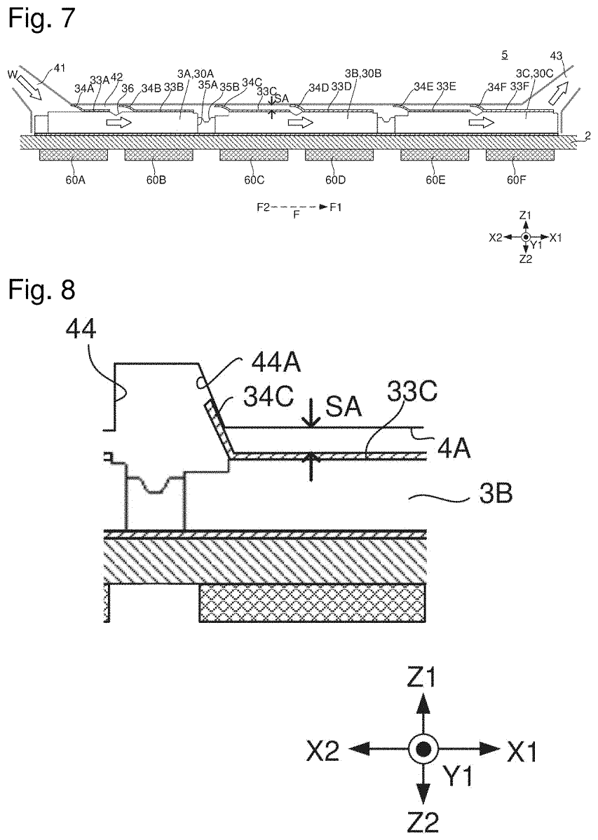

FIG. 7 is a side sectional view of a cooling device 5 according to a second example embodiment. In the cooling device 5 illustrated in FIG. 7, a fin is divided into fins 3A, 3B, and 3C. The fins 3A, 3B, and 3C are arranged in this order from the other side in the first direction toward the one side in the first direction. By stacking a plurality of fins 3A, 3B, and 3C in the second direction respectively, fin groups 30A, 30B, and 30C are configured. That is, the heat dissipator 1 includes the fin groups 30A, 30B, and 30C.

In the configuration illustrated in FIG. 7, the heating elements 60A, 60B, 60C, 60D, 60E, and 60F are disposed on the other side in the third direction of the base portion 2. The heating elements 60A and 60B are disposed on the other side in the first direction and one side in the first direction of a notch 36 to be described later formed in the fin 3A. The heating elements 60C and 60D and the heating elements 60E and 60F are similar with respect to the fins 3B and 3C.

Between the fin 3A and the fin 3B, a recess 35A recessed to the base portion 2 is provided on the other side in the third direction. In addition, a recess 35B recessed to the middle of the other side in the third direction is provided between the fin 3A and the fin 3B. The recesses 35A and the recesses 35B are alternately arranged in the second direction. Such recesses 35A and 35B form an open slot extending in the second direction.

The open slot can break the boundary layer of the flow developed in the side plate portion 31 of the fin 3A. With the open slot, the refrigerant W having a high temperature after passing through the heating elements 60A and 60B disposed at the center in the second direction as viewed in the third direction and the refrigerant W having a low temperature after passing through both sides of the heating elements 60A and 60B in the second direction can be mixed in the second direction.

The fin 3B is provided with a first top plate portion 33C and a second top plate portion 33D divided in the second direction. At the end on the other side in the first direction of the first top plate portion 33C on the other side in the first direction, a bent portion 34C is provided. That is, the bent portion 34C is disposed near the open slot. By sealing the gap SA by the bent portion 34C, the refrigerant W is prevented from flowing from the open slot into the gap SA, and the refrigerant W is guided from the open slot to the flow path between the fins 3B. Therefore, the heating elements 60C and 60D can be cooled efficiently.

In other words, the recesses 35A and 35B recessed to the other side in the third direction are provided between the first fin 3A that is a fin on the other side in the first direction and the second fin 3B that is a fin adjacent to the first fin 3A one side in the first direction. At the end on the other side in the first direction of the top plate portion 33C provided to the second fin 3B, the bent portion 34C is provided. Thus, the refrigerant W can be prevented from flowing from the open slot provided between the first fin 3A and the second fin 3B into the gap SA in the third direction between the top plate portion 33C and the liquid cooling jacket 4. Therefore, the refrigerant W can be guided between the second fins 3B.

Note that an open slot is provided between the fin 3B and the fin 3C, and a bent portion 34E provided to the fin 3C is disposed near the open slot. As a result, the same effect as described above can be obtained.

The side plate portion 31 of the fin 3A is provided with a notch 36 that is notched on the other side in the third direction. A first top plate portion 33A and a second top plate portion 33B are provided on the other side in the first direction and one side in the first direction of the notch 36, respectively. That is, in the same fin 3A, the first top plate portion 33A that is a top plate portion disposed on the other side in the first direction and the second top plate portion 33B that is a top plate portion adjacent to one side in the first direction of the first top plate portion 33A are provided. A bent portion 34A is provided at the end on the other side in the first direction of the first top plate portion 33A, and a bent portion 34B is provided at the end on the other side in the first direction of the second top plate portion 33B. The bent portion 34B disposed in the middle of the first direction in the fin 3A can be easily formed by cutting and bending the top plate portion 33B.

In particular, since the top plate portion is divided on both sides in the first direction of the notch 36, the bent portion 34B can be formed. The notch 36 makes it possible to break a boundary layer developed in the side plate portion 31 on the upstream side or to mix the refrigerants W having different temperatures in the second direction. The bent portion 34B guides the refrigerant W in the vicinity of the notch 36 between the fins 3A on the downstream side, and can efficiently cool the heating element 60B.

The same applies to the bent portions 34C, 34D, 34E, and 34F provided to the fins 3B and 3C.

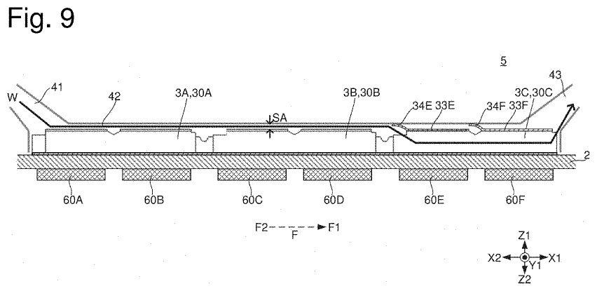

As illustrated in FIG. 8, the top surface 4A of the liquid cooling jacket 4 may be provided with a top surface recess 44 recessed to one side in the third direction. The bent portion 34C provided to the fin 3B is in surface contact with the wall portion 44A on one side in the first direction in the top surface recess 44. That is, the liquid cooling jacket 4 includes the top surface 4A disposed on one side in the third direction of the top plate portion 33C and provided with the gap SA in the third direction between the top surface 4A and the top plate portion 33C, and the top surface 4A is provided with the top surface recess 44 that is recessed toward one side in the third direction and faces the bent portion 34C in the first direction. By providing the top surface recess 44 in this manner, it is easy to more reliably seal the gap SA by the bent portion 34C disposed in the middle of the first direction.

The top surface recesses may be provided for the bent portions 34B, 34D, 34E, and 34F. Further, the bent portion may be disposed with a gap between it and the top surface recess in the first direction.

FIG. 9 is a side cross-sectional view of a cooling device 5 according to a third example embodiment. The present example embodiment is different from the above-described second example embodiment (FIG. 7) in that bent portions are not provided to the fins 3A and 3B on the upstream side, and the bent portions 34E and 34F are provided only to the fin 3C on the most downstream side.

That is, a plurality of fin groups 30A, 30B, and 30C, configured by arranging the fins 3A, 3B, and 3C in the second direction, are provided in the first direction, and the bent portions 34E and 34F are provided only for the fin group 30C closest to one side in the first direction among the fin groups 30A, 30B, and 30C. As a result, since no bent portion is provided for the fin groups on the upstream side, the gap SA between the fins 3A and 3B and the liquid cooling jacket 4 is not sealed on the upstream side. Therefore, the low-temperature refrigerant W flows through the unsealed gap SA. Since the gap SA between the fin 3C and the liquid cooling jacket 4 is sealed by the bent portions 34E and 34F on the most downstream side, the low-temperature refrigerant W is guided between the fins 3C, and the cooling performance can be improved on the most downstream side where the necessity of the cooling performance is high.

The example embodiments of the present disclosure have been described above. Note that the scope of the present disclosure is not limited to the above example embodiments. The present disclosure can be implemented by making various changes to the above-described example embodiments without departing from the gist of the disclosure. The matters described in the above example embodiments can be optionally combined together, as appropriate, as long as there is no inconsistency.

For example, the fin group is not limited to the stacked fins, and a plurality of pin fins protruding in a columnar shape from the base portion 2 to one side in the third direction may be arranged. In this case, the top plate portion is provided at one end in the third direction of the pin fin.

For example, a vapor chamber or a heat pipe may be provided between the heating element and the heat dissipator.

As described above, a cooling device according to one aspect of the present disclosure is a cooling device that includes a liquid cooling jacket and a heat dissipator.

The heat dissipator includes
a base portion in a plate shape, the base portion extending in a first direction along a direction in which a refrigerant flows and in a second direction orthogonal to the first direction, and having a thickness in a third direction orthogonal to the first direction and the second direction,
a fin protruding from the base portion toward one side in the third direction,
a top plate portion provided at an end on the one side in the third direction of the fin, and
a bent portion bent toward the one side in the third direction at at least one of an end on one side in the first direction and an end on other side in the first direction of the top plate portion, with the one side in the first direction being a downstream side.

A gap in the third direction is provided between the liquid cooling jacket and the top plate portion, and
the bent portion faces the liquid cooling jacket (first configuration).

Further, in the first configuration, the bent portion may face the liquid cooling jacket while being in contact with the liquid cooling jacket (second configuration).

Further, in the second configuration, the bent portion may be configured as a leaf spring (third configuration).

Further, in any of the first to third configurations, the distal end of the bent portion bent from an end on the other side in the first direction of the top plate portion may face the other side in the first direction (fourth configuration).

Further, in the fourth configuration, the bent portion may be in surface contact with the liquid cooling jacket while facing the liquid cooling jacket in the first direction (fifth configuration).

Further, in the fourth configuration, the bent portion may have a second facing surface that faces a first facing surface of the liquid cooling jacket via a gap in the first direction (sixth configuration).

Further, in the fifth or sixth configuration, the liquid cooling jacket may have a top surface that is disposed on one side in the third direction of the top plate portion and has a gap in the third direction between the liquid cooling jacket and the top plate portion, and
the top surface may have a top surface recess that is recessed toward the one side in the third direction and faces the bent portion in the first direction (seventh configuration).

Further, in any of the first to seventh configurations, a recess recessed to the other side in the third direction may be provided between a first fin that is the fin on the other side in the first direction and a second fin that is the fin adjacent to the one side in the first direction of the first fin, and
the bent portion may be provided at the end on the other side in the first direction of the top plate portion provided to the second fin (eighth configuration).

Further, in any of the first to eighth configurations, in the same fin, a first top plate portion that is the top plate portion disposed on the other side in the first direction and a second top plate portion that is the top plate portion adjacent to the first top plate portion on the one side in the first direction may be provided, and
the bent portion may be provided to the end on the other side in the first direction of the second top plate portion (ninth configuration).

Further, in any of the first to ninth configurations, a plurality of fin groups, each configured of the fins arranged in the second direction, may be provided in the first direction, and
the bent portion may be provided only for a fin group closest to the one side in the first direction, among the plurality of fin groups (tenth configuration).

The present disclosure can be used for cooling various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a liquid cooling jacket; and
a heat dissipator, wherein
the heat dissipator includes:
a base portion with a plate shape and extending in a first direction along a direction in which a refrigerant flows and in a second direction perpendicular or substantially perpendicular to the first direction, and having a thickness in a third direction perpendicular or substantially perpendicular to the first direction and the second direction;
a fin protruding from the base portion toward one side in the third direction;
a top plate portion provided at an end on the one side in the third direction of the fin; and
a bent portion bent toward the one side in the third direction at at least one of an end on one side in the first direction and an end on other side in the first direction of the top plate portion, with the one side in the first direction being a downstream side;
a gap in the third direction is provided between the liquid cooling jacket and the top plate portion; and
the bent portion opposes the liquid cooling jacket.

2. The cooling device according to claim 1, wherein the bent portion opposes the liquid cooling jacket while contacting the liquid cooling jacket.

3. The cooling device according to claim 2, wherein the bent portion includes a leaf spring.

4. The cooling device according to claim 1, wherein a distal end of the bent portion bent from the end on the other side in the first direction of the top plate portion opposes the other side in the first direction.

5. The cooling device according to claim 4, wherein the bent portion is in surface contact with the liquid cooling jacket while opposing the liquid cooling jacket in the first direction.

6. The cooling device according to claim 4, wherein the bent portion includes a second facing surface that opposes a first facing surface of the liquid cooling jacket through a gap in the first direction.

7. The cooling device according to claim 5, wherein the liquid cooling jacket includes a top surface that is located on one side in the third direction of the top plate portion and includes a gap in the third direction between the liquid cooling jacket and the top plate portion; and
the top surface is provided with a top surface recess that is recessed toward the one side in the third direction and opposes the bent portion in the first direction.

8. The cooling device according to claim 1, wherein
a recess recessed toward the other side in the third direction is provided between a first fin that is the fin on the other side in the first direction and a second fin that is the fin adjacent to the first fin on the one side in the first direction; and
the bent portion is provided at the end on the other side in the first direction of the top plate portion provided to the second fin.

9. The cooling device according to claim 1, wherein
in the fin, a first top plate portion that is the top plate portion located on the other side in the first direction and a second top plate portion that is the top plate portion adjacent to the first top plate portion on the one side in the first direction are provided; and
the bent portion is provided at an end on the other side in the first direction of the second top plate portion.

10. The cooling device according to claim 1, wherein
a plurality of fin groups, each including the fins arranged in the second direction, are provided in the first direction; and
the bent portion is provided only for a fin group closest to the one side in the first direction, among the plurality of fin groups.
